(19) United States
(12) Patent Application Publication
(10) Pub. No.: US 2021/0320277 A1
(43) Pub. Date: Oct. 14, 2021

(54) DISPLAY SUBSTRATE, DISPLAY DEVICE AND METHOD OF MANUFACTURING DISPLAY SUBSTRATE

(71) Applicant: BOE TECHNOLOGY GROUP CO., LTD., BEIJING (DE)

(72) Inventors: Guoying WANG, BEIJING (CN); Zhen SONG, BEIJING (CN)

(73) Assignee: BOE TECHNOLOGY GROUP CO., LTD., BEIJING (CN)

(21) Appl. No.: 17/273,772

(22) PCT Filed: May 27, 2020
(86) PCT No.: PCT/CN2020/092699

§ 371 Date: Mar. 5, 2021

(30) Foreign Application Priority Data
Jun. 21, 2019 (CN) 201910542427.7

(51) Int. Cl. H01L 51/52; H01L 51/56

(52) U.S. Cl. CPC H01L 51/5246; H01L 51/5228; H01L 51/5212; H01L 51/56

(57) ABSTRACT

There are provided a display substrate, a display device, and a method of manufacturing the display substrate. The display substrate comprises a planarization layer; a pixel definition layer on the planarization layer, wherein the pixel definition layer comprises an opening and a rib surrounding the opening; a first electrode on the planarization layer and within the opening; a light-emitting portion located within the opening and electrically connected to the first electrode; an auxiliary electrode on the rib of the pixel definition layer; an insulating portion between the first electrode and the auxiliary electrode; and a second electrode covering the auxiliary electrode and the light-emitting portion.

### CROSS-REFERENCE TO RELATED APPLICATIONS

This application claims priority under 35 U.S.C. § 371 to International Patent Application No. PCT/CN2020/092699 filed on May 27, 2020, which claims the priority to the Chinese Patent Application No. 201910542427.7 filed on Jun. 21, 2019.

### TECHNICAL FIELD

This disclosure relates to a display substrate, a display device, and a method of manufacturing the display substrate.

### BACKGROUND

OLEDs (Organic Light Emitting Diodes) are widely used in various display devices. When an OLED pixel is powered, luminance uniformity of the pixel can be improved by arranging an auxiliary electrode.

### SUMMARY

According to an aspect of the present disclosure, there is provided a display substrate comprising a planarization layer; a pixel definition layer on the planarization layer, wherein the pixel definition layer comprises an opening and a rib surrounding the opening; a first electrode on the planarization layer and within the opening; a light-emitting portion located within the opening and electrically connected to the first electrode; an auxiliary electrode on the rib of the pixel definition layer; an insulating portion between the first electrode and the auxiliary electrode; and a second electrode covering the auxiliary electrode and the light-emitting portion.

In some embodiments, the insulating portion partially covers at least one of the first electrode and the auxiliary electrode.

In some embodiments, the insulating portion covers at least one of: an edge portion of a surface of the auxiliary electrode away from the planarization layer; and an edge portion of a surface of the first electrode away from the planarization layer.

In some embodiments, the insulating portion partially covers the auxiliary electrode, and a maximum thickness of a portion of the insulating portion covering the auxiliary electrode in a direction perpendicular to the planarization layer is between 1000 Å and 2000 Å.

In some embodiments, the light-emitting portion comprises a functional layer formed from a precursor material, the rib comprises a single layer structure, and hydrophobicity of the insulating portion to the precursor material is higher than that of the single layer structure to the precursor material.

In some embodiments, the light-emitting portion comprises a functional layer formed from a precursor material, the rib comprises a stack of a plurality of layer structures, and hydrophobicity of the insulating portion to the precursor material is higher than that of a layer structure having a lowest hydrophobicity to the precursor material among the plurality of layer structures.

In some embodiments, the insulating portion covers a sidewall of the rib.

In some embodiments, the sidewall and an upper surface of the planarization layer form an acute angle.

In some embodiments, the insulating portion comprises a water and oxygen barrier material.

According to another aspect of the present disclosure, there is provided a display device comprising the display substrate according to any of embodiments of the present disclosure.

According to still another aspect of the present disclosure, there is provided a method of manufacturing the display substrate, comprising: forming a planarization layer; forming a pixel definition layer on the planarization layer, wherein the pixel definition layer comprises an opening and a rib surrounding the opening; simultaneously forming an auxiliary electrode on the rib of the pixel definition layer and a first electrode on a portion of the planarization layer corresponding to the opening; forming an insulating portion between the auxiliary electrode and the first electrode, wherein the insulating portion electrically insulates the auxiliary electrode from the first electrode; forming a light-emitting portion on the first electrode; and forming a second electrode on the auxiliary electrode and the light-emitting portion.

In some embodiments, simultaneously forming the auxiliary electrode on the rib of the pixel definition layer and the first electrode on the portion of the planarization layer corresponding to the opening comprises: simultaneously forming a first electrode stack and an auxiliary electrode stack in one patterning process, wherein the auxiliary electrode stack comprises the auxiliary electrode and a photoresist on a side of the auxiliary electrode away from the planarization layer, and the first electrode stack comprises the first electrode and a photoresist on a side of the first electrode away from the planarization layer; and forming the insulating portion between the auxiliary electrode and the first electrode, comprising: partially asking the photoresist on the side of the auxiliary electrode away from the planarization layer and the photoresist on the side of the first electrode away from the planarization layer to expose an edge region of the auxiliary electrode and an edge region of the first electrode; depositing an insulating material layer; and stripping an unashed photoresist on the auxiliary electrode and an unashed photoresist on the first electrode, to make the insulating material on the stripped unashed photoresist removed and an unremoved insulating material forms the insulating portion.

In some embodiments, simultaneously forming the first electrode stack and the auxiliary electrode stack in one patterning process comprises: depositing an electrode material layer on the rib of the pixel definition layer and the portion of the planarization layer corresponding to the opening; coating a photoresist layer on the electrode material layer; exposing and developing the photoresist layer on the electrode material layer to expose a portion of the electrode material layer; and etching the exposed portion of the electrode material layer to obtain the first electrode stack and the auxiliary electrode stack.

### BRIEF DESCRIPTION OF THE DRAWINGS

The embodiments of the present disclosure will now be described in detail with reference to the accompanying drawings, in which:

FIG. 1 schematically illustrates a cross-sectional view of a display substrate according to an embodiment of the present disclosure;

FIG. 2 schematically illustrates a cross-sectional view of a display substrate according to another embodiment of the present disclosure;

FIG. 3 schematically illustrates a flowchart of a method of manufacturing a display substrate according to an embodiment of the present disclosure;

FIGS. 4A to 4C schematically illustrate cross-sectional views of intermediate structures of a display substrate in a method of manufacturing a display substrate according to an embodiment of the present disclosure;

FIGS. 5A and 5B schematically illustrate cross-sectional views of intermediate structures of a display substrate in a method of manufacturing a display substrate according to another embodiment of the present disclosure;

FIG. 6 schematically illustrates a flowchart of a method of manufacturing a display substrate according to another embodiment of the present disclosure;

FIG. 7 schematically illustrates a flowchart of a method of manufacturing a display substrate according to still another embodiment of the present disclosure; and

FIGS. 8A to 8C schematically illustrate cross-sectional views of intermediate structures of a display substrate in a method of manufacturing a display substrate according to still another embodiment of the present disclosure.

It should be understood that the drawings are merely schematic and are not necessarily drawn to scale. Throughout the drawings, identical reference numerals denote identical or similar parts.

### DETAILED DESCRIPTION

A display substrate, a display device, and a method of manufacturing the display substrate according to the present disclosure will be further described with reference to the accompanying drawings. It should be understood that the following description is only intended to explicate the present disclosure, and not to limit the scope of the present disclosure.

OLEDs are widely used in various display devices due to their many advantages such as high light-emitting efficiency, low power consumption, high contrast, and high response speed. According to relationship between a direction of light emitted from a light-emitting portion and a base substrate, an OLED display panel generally has two light-emitting modes: top emission and bottom emission, that is, the bottom emission mode with a direction of light emitted toward the base substrate, and the top emission mode with a direction of light emitted away from the base substrate. In the bottom emission mode, light emitted from the light-emitting portion is blocked by a component such as a thin film transistor on the substrate. Therefore, the top emission mode can achieve higher resolution and larger aperture ratio than the bottom emission mode, and thus is more popular. Each OLED pixel in the OLED display panel in the top emission mode can comprise a common electrode, e.g., a common cathode. Since the common electrode spans a plurality of pixels, there may be a voltage drop on it, i.e., the potential is not uniform throughout the common electrode. This may affect luminance uniformity of each pixel. In order to reduce the voltage drop on the common electrode, an auxiliary electrode can be provided in the display substrate. The auxiliary electrode provides an electric signal to the common electrode, so as to reduce the influence of the voltage drop. In general, it is necessary to utilize a metal of gate and source-drain layers of a driving transistor of the OLED to manufacture the auxiliary electrode. The auxiliary electrode is connected to the common electrode through via holes in the planarization layer and a rib of the pixel definition layer. In order to accommodate the via holes, the rib of the pixel definition layer needs to have a large extension in a plane parallel to the planarization layer, which results in a lower aperture ratio of the display panel. In addition, since the via hole is deeper and the material of the common electrode is usually a transparent conductive oxide one, a lap joint between the common electrode and the auxiliary electrode is easily broken, which affects the product yield.

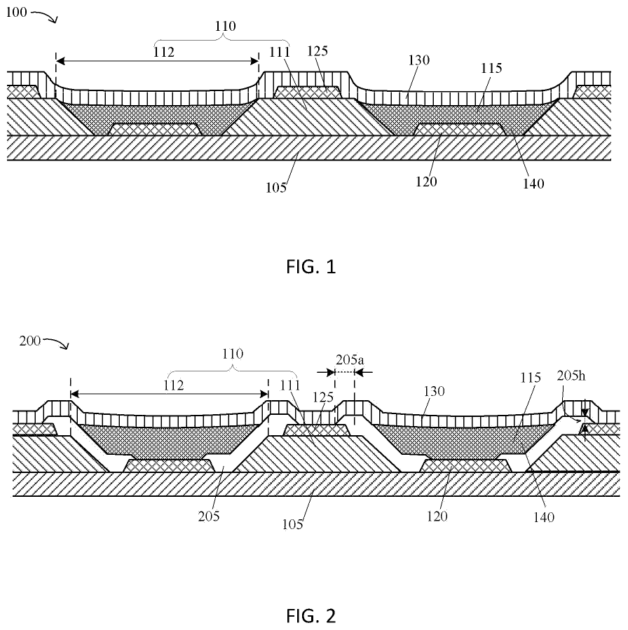

According to an aspect of the present disclosure, there is provided a display substrate. FIG. 1 schematically illustrates a structure of a display substrate 100 according to an embodiment of the present disclosure. The display substrate 100 comprises a planarization layer 105 and a pixel definition layer 110 on the planarization layer 105. In some embodiments, the planarization layer 105 can be formed from resin. The pixel definition layer 110 can be made of an organic insulating material, including but not limited to a polysiloxane based material, an acrylic based material, or a polyimide based material, etc. The pixel definition layer 110 comprises a rib 111 and an opening 112 defined by the rib 111. The display substrate 100 further comprises a first electrode 120 on the planarization layer 105 and within the opening 112. The first electrode 120 can be electrically connected to a pixel driving circuit within and/or below the planarization layer 105. For clarity and conciseness of the figures, the pixel driving circuit and other elements within and/or below the planarization layer have been omitted in the figures. In addition, the pixel driving circuit can employ a top-gate type pixel driving transistor or a bottom-gate type pixel driving transistor, such as a Back Channel Etching (BCE) transistor and an Etch Stop layer (ESL) transistor. The display substrate further comprises a light-emitting portion 115 within the opening 112, which is electrically connected to the first electrode 120. The display substrate further comprises an auxiliary electrode 125 on the rib 111 of the pixel definition layer 110 and a second electrode 130 covering the auxiliary electrode 125 and the light-emitting portion 115. The auxiliary electrode 125 and the light-emitting portion 115 are electrically connected to the second electrode 130, respectively. In some embodiments, the first electrode 120 can be an anode of a pixel, and the second electrode 130 can be a common cathode of each pixel of the display substrate. The light-emitting portion 115 can comprise one or more functional layers. For example, the functional layer can comprise, for example, a hole injection layer, a hole transport layer, a light-emitting material layer, an electron injection layer, an electron transport layer and so on.

Since the auxiliary electrode in the display substrate of the present disclosure is arranged on the rib of the pixel definition layer, it no longer needs to be connected to the second electrode through a via hole in the rib, so that the via hole can be omitted, and the extension of the rib on the plane where the planarization layer is in can be reduced, thereby improving the aperture ratio of the display panel. In addition, since the auxiliary electrode is in direct contact with the second electrode, the problem that the lap joint is easily broken is improved.

FIG. 2 schematically illustrates a structure of a display substrate 200 according to another embodiment of the present disclosure. As shown in FIG. 2, the display substrate 200 further comprises an insulating portion 205. The insulating portion 205 is arranged between the first electrode 120 and the auxiliary electrode 125. The insulating portion 205 can further prevent a short circuit between the first electrode 120 and the auxiliary electrode 125, thereby further improving the yield of the display substrate. In some embodiments, the rib 111 comprises a top surface and a sidewall, and the insulating portion 205 is arranged on the sidewall of the rib 111. In some embodiments, the sidewall of the rib 111 can be sloping. For example, the sidewall of the rib 111 and an upper surface of the planarization layer 105 form an acute angle. In some embodiments, this can be interpreted that an aperture of the opening 112 increases progressively in a direction away from the planarization layer 105. The sloping sidewall helps to make the insulating portion 205 better cover the rib 111.

In some embodiments, the insulating portion 205 partially covers at least one of the first electrode 120 and the auxiliary electrode 125. Phrases such as “at least one of a first element and a second element” mean that there are three cases, i.e., only the first element, only the second element, and both the first element and the second element. In conjunction with the present disclosure, the insulating portion 205 can only partially cover the first electrode 120, only partially cover the auxiliary electrode 125, or partially cover both. In the embodiment shown in FIG. 2, the insulating portion 205 partially covers both the first electrode 120 and the auxiliary electrode 125. In a more specific embodiment, the insulating portion 205 covers an edge portion of a surface of the auxiliary electrode 125 away from the planarization layer 105 and/or an edge portion of a surface of the first electrode 120 away from the planarization layer 105. The term “and/or” means any one or any combination of items connected thereby. For example, the expression “the insulating portion 205 covers an edge portion of a surface of the auxiliary electrode 125 away from the planarization layer 105 and/or an edge portion of a surface of the first electrode 120 away from the planarization layer 105” comprises the following solutions: the insulating portion 205 covering only an edge portion of a surface of the auxiliary electrode 125 away from the planarization layer 105, the insulating portion 205 covering only an edge portion of a surface of the first electrode 120 away from the planarization layer 105, and the insulating portion 205 covering both an edge portion of a surface of the auxiliary electrode 125 away from the planarization layer 105 and an edge portion of a surface of the first electrode 120 away from the planarization layer 105. With this arrangement, the edge portions of the first electrode 120 and/or the auxiliary electrode 125 can be wrapped to enhance electric insulation effect. Meanwhile, this arrangement can prevent a precursor material of a functional layer of the light-emitting portion 115 from overflowing onto the auxiliary electrode 125 during the progress of manufacturing the display substrate.

In some embodiments, as shown in FIG. 2, the insulating portion 205 partially covers the auxiliary electrode 125 (e.g., covers an edge portion of an upper surface of the auxiliary electrode 125), and a maximum thickness 205h of a portion 205a of the insulating portion 205 covering the auxiliary electrode 125 is between 1000 Å and 2000 Å in a direction perpendicular to the planarization layer 105. In this case, a drop of the second electrode 130 from the insulating portion 205 to the auxiliary electrode 125 is not excessively high, thereby optimizing a lap joint effect between the second electrode 130 and the auxiliary electrode 125, and improving the reliability of electric connection between the two. Additionally, in some embodiments, the thickness of the second electrode 130 can be greater than 1000 Å.

In some embodiments, the light-emitting portion 115 comprises a functional layer. The functional layer can be formed by printing and drying a precursor material. When manufacturing the functional layer, the precursor material is liquid. Since the rib 111 may contain a hydrophilic material with respect to the precursor material (for example, there may be a fluorine-containing resin material in the rib, which is hydrophilic relative to the precursor material), moisture in the precursor material may climb along the side of the rib 111 due to wetting effect. Droplets of the precursor material may even overflow the rib when they are large. Therefore, the light-emitting portion 115 finally obtained after drying the precursor material may not be flat (for example, an upper surface of the light-emitting portion may be curved, that is, the uniformity of the thickness of the light-emitting portion becomes poor). This may result in uneven luminance of each pixel. Moreover, the uniformity problem will be magnified with the increase of the number of the functional layers printed. For this purpose, the material of the insulating portion 205 can be selected to make the hydrophobicity of the insulating portion 205 with respect to the precursor material of the functional layer higher than that of the ribs 111 with respect to the precursor material. For example, the rib 111 may be composed of a single layer structure, or may be a stack comprising a plurality of layer structures. For the rib composed of a single-layer structure, in order to improve the problem that the precursor material climbs on the side of the rib, the hydrophobicity of the insulating portion with respect to the precursor material can be made higher than that of the single-layer structure with respect to the precursor material. For the rib comprising a plurality of layer structures, the hydrophobicity of the insulating portion with respect to the precursor material can be made higher than that of a layer with a lowest hydrophobicity with respect to the precursor material among the plurality of layer structures. For example, in some embodiments, the rib comprises an acrylic based material layer and a fluorine-containing resin material layer. Since the fluorine-containing resin material layer has a lower hydrophobicity with respect to the precursor material than the acrylic material layer, the climbing problem above can be improved by selecting the insulating portion such that it has a higher hydrophobicity with respect to the precursor material than the fluorine-containing resin material layer. Obviously, the material of the insulating portion can be selected to make the insulating portion have a higher hydrophobicity with respect to the precursor material than each layer among the plurality of layer structures. In this way, the degree of climbing of the edge of the functional layer along the insulating portion 205 is significantly less than that along the rib 111. Therefore, the existence of the insulating portion 205 can alleviate the problem that the functional layer climbs along the sidewall of the rib 111, which helps to improve uniformity of pixel luminance.

In some embodiments, the insulating portion 205 can comprise a water and oxygen barrier material. Typically, the material of the rib 111 contains water and oxygen components. During the manufacturing and use of the display substrate, the water and oxygen components may escape from the rib 111 and corrode other elements in the display substrate. Since the insulating portion 205 comprises the water and oxygen barrier material and is arranged on the sidewall of the rib 111, it can prevent the water and oxygen components from diffusing into an inside of the display substrate, which improves the reliability of the display substrate. In some embodiments, the water and oxygen barrier material comprises silicon oxide, silicon nitride, or silicon oxynitride, as well as other materials that can block water and oxygen diffusion.

In some embodiments, the materials of the auxiliary electrode 125 and the first electrode 120 can be the same. In this way, the auxiliary electrode 125 and the first electrode 120 can be formed by a same patterning process and a same mask in the process of manufacturing the display substrate. This saves the process of manufacturing the display substrate and the number of masks required.

In some embodiments, the materials of the auxiliary electrode 125 and the first electrode 120 are a same reflective metal, i.e., the light-emitting mode of the light-emitting portion 115 is a top emission mode. In this case, light emitted from the light-emitting portion 115 is reflected by the first electrode 120, and travels in a direction from the first electrode 120 to the second electrode 130 (which can be a transparent electrode) after being reflected. That is, the light emitted from the light-emitting portion 115 does not pass a pixel driving circuit, and therefore the pixel driving circuit will not affect the display effect. In addition, whether a base substrate of the display substrate is transparent or not will not affect the display effect either. In some embodiments, the auxiliary electrode 125 and the second electrode 130 can be a single-layer structure formed from a single metal (e.g., Ag, Cu, Al, Mo, etc.); or a multi-layer stack structure formed from a plurality of metals, e.g., a MoNb/Cu/MoNb stack; or a single-layer structure formed from an alloy material (e.g., AlNd or MoNb, etc.); or a multi-layer stack structure of metals and transparent conductive oxides (e.g., ITO, AZO, etc.), e.g., an ITO/Ag/ITO stack. Other suitable materials and structures can also be used for the auxiliary electrode 125 and the second electrode 130, and are not limited by the present disclosure.

According to the display substrate of the present disclosure, since the auxiliary electrode is formed on the rib, the rib does not need to accommodate a via hole, which makes the aperture ratio of the display substrate increased. Also, in some embodiments, the display substrate comprises the insulating portion arranged between the first electrode and the auxiliary electrode, which enhances electrical insulation between the first electrode and the auxiliary electrode, reduces the climbing of the light-emitting portion on the rib, and improves display uniformity of the pixel. Moreover, the insulating portion can wrap the edge portions of the first electrode and the auxiliary electrode, thereby enhancing electric insulation effect. In addition, the insulating portion can further prevent water and oxygen diffusion inside the display substrate, which improves the reliability of the display substrate.

According to another aspect of the present disclosure, there is provided a display device comprising the display substrate according to the embodiments of the present disclosure. The display device has various advantages of the display substrate according to the present disclosure, which is not described in detail herein. The display device can be used for any product or component with a display function, such as a mobile phone, a tablet computer, a television set, a display, a notebook computer, a digital photo frame, a navigator and the like.

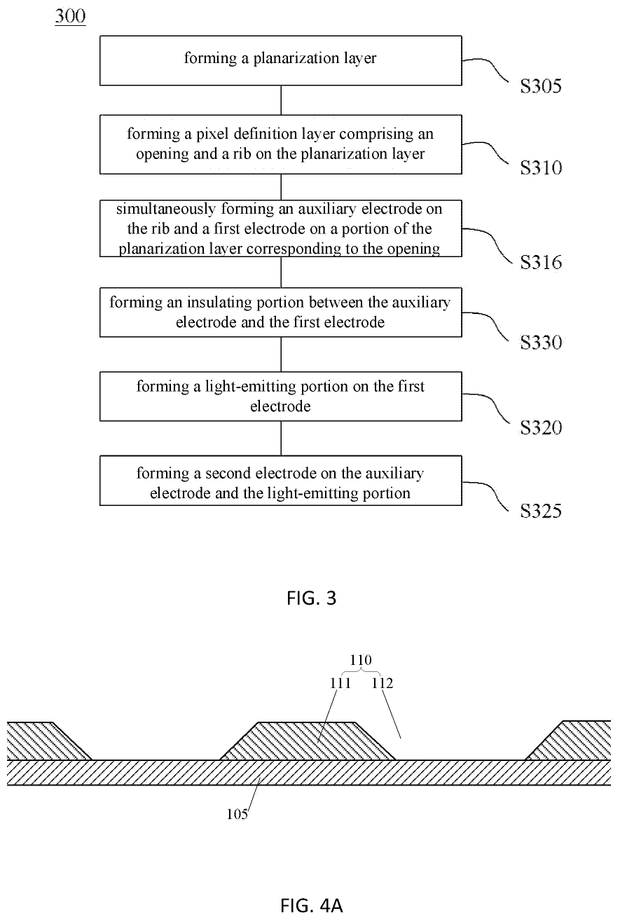

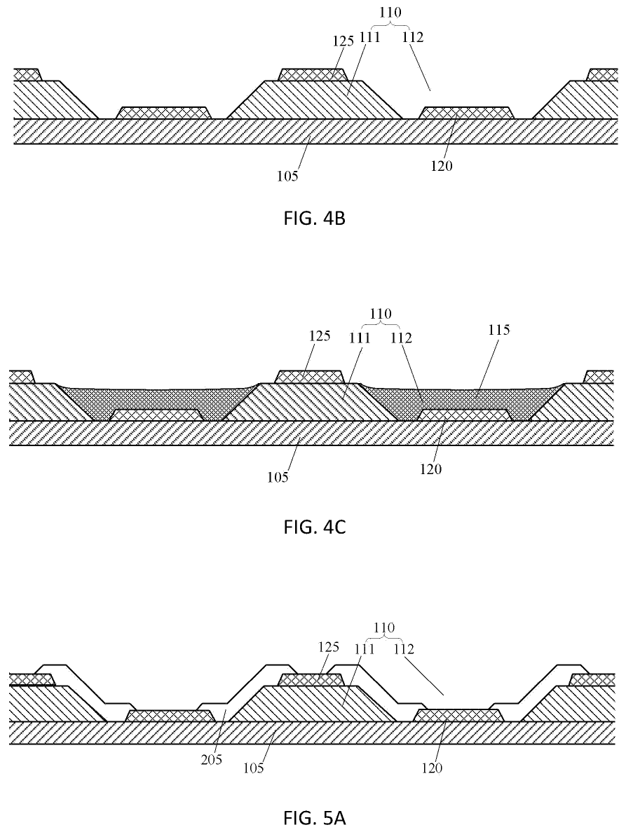

According to still another aspect of the present disclosure, there is provided a method of manufacturing a display substrate. FIG. 3 schematically illustrates a flowchart of a method 300 of manufacturing a display substrate according to an embodiment of the present disclosure. FIGS. 4A to 4C schematically illustrate cross-sectional views of various intermediate structures of a display substrate in a method of manufacturing a display substrate according to the present disclosure. As shown in FIG. 3, the method 300 comprises the following steps.

In step S305, a planarization layer is formed.

In step S310, a pixel definition layer is formed on the planarization layer, wherein the pixel definition layer comprises an opening and a rib surrounding the opening.

In step S315, an auxiliary electrode is formed on the rib and a first electrode is formed on a portion of the planarization layer corresponding to the opening of the pixel definition layer.

In step S320, a light-emitting portion is formed on the first electrode.

In step S325, a second electrode is formed on the auxiliary electrode and the light-emitting portion.

The method 300 of manufacturing a display substrate according to the present disclosure is described in detail below. First, a base substrate is provided, on which components (not shown in the figure) such as active matrixes, various wiring, pixel capacitors are formed. Thereafter, the planarization layer 105 is formed on the base substrate on which the components are formed (step S305). A material of the planarization layer 105 can be, for example, resin. Then, the pixel definition layer 110 is formed on the planarization layer 105 (step S310), wherein the pixel definition layer 110 comprises the opening 112 and the rib 111. FIG. 4A schematically illustrates a cross-sectional view of an intermediate structure of the display substrate of the planarization layer 105 and the pixel definition layer 110 formed after step S310. For simplicity and clarity of the drawings, the components such as active matrixes, various wiring, pixel capacitors are omitted in the drawings.

Thereafter, the auxiliary electrode 125 is formed on the rib 111 of the pixel definition layer 110, and the first electrode 120 is formed on the portion of the planarization layer 105 corresponding to the opening 112 of the pixel definition layer (step S315). After this step, the first electrode 120 is formed within the opening 112. The first electrode 120 is electrically connected to a pixel driving circuit within or under the planarization layer 105. The auxiliary electrode 125 and the first electrode 120 can be formed through a patterning process. For example, the auxiliary electrode 125 and the first electrode 120 can be respectively formed by steps of forming an electrode material layer, coating a photoresist, exposing and developing the photoresist using a mask, etching the electrode material layer, and etc. FIG. 4B schematically illustrates a cross-sectional view of an intermediate structure of the display substrate after the first electrode 120 and the auxiliary electrode 125 are formed.

After the first electrode 120 is formed, the light-emitting portion 115 is formed on the first electrode 120 (step S320). The functional layer in the light-emitting portion 115 can be formed through, for example, an inkjet printing process. Taking a luminescent material layer as an example, the inkjet printing process can refer to, for example, a process of ejecting a mixture of the luminescent material and a solvent (i.e., a precursor material) into a predetermined position (e.g., within the opening 112), and drying the mixture to remove the solvent and retain the luminescent material to form the luminescent material layer. FIG. 4C schematically illustrates a cross-sectional view of an intermediate structure of the display substrate after the light-emitting portion 115 is formed.

Thereafter, the second electrode 130 is formed on the auxiliary electrode 125 and the light-emitting portion 115 (step S325). Specifically, a continuous layer of a second electrode material can be deposited (e.g., through processes such as Plasma Enhanced Chemical Vapor Deposition (PECVD)) on the auxiliary electrode 125 and the light-emitting portion 115. The second electrode material can be a transparent conductive one, such as ITO. For a single pixel, the second electrode 130 covers the light-emitting portion 115 such that the light-emitting portion 115 is interposed between the first electrode 120 and the second electrode 130. Each second electrode 130 on the display substrate can be connected together to form a common electrode. The second electrode 130 is electrically connected to the auxiliary electrode 125. The auxiliary electrode 125 can provide an electric signal for the second electrode 130 to reduce a voltage drop of the second electrode and to improve luminance uniformity of each pixel. A cross-sectional view of the display substrate after the second electrode 130 is formed is shown in FIG. 1.

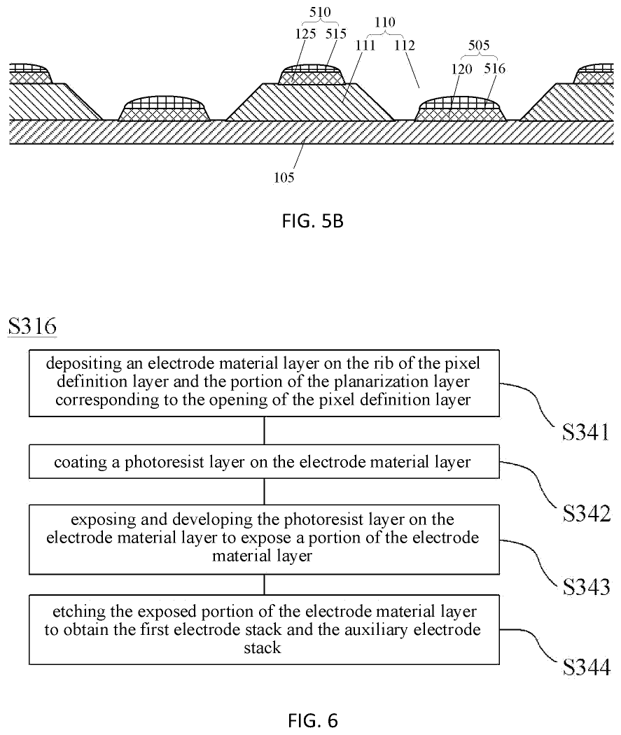

In some embodiments, the method 300 further comprises: forming an insulating portion 205 between the auxiliary electrode 125 and the first electrode 120 (step S330), wherein the insulating portion 205 electrically insulates the auxiliary electrode 125 from the first electrode 120. As described above, the insulating portion 205 can enhance electric insulation between the auxiliary electrode 125 and the first electrode 120. Step S330 can be performed between step S315 and step S320, i.e., after the first electrode 120 and the auxiliary electrode 125 have been formed, the insulating portion 205 is formed between the two. The insulating portion 205 can partially cover at least one of the auxiliary electrode 125 and the first electrode 120. For example, the insulating portion 205 can cover an outer edge of the auxiliary electrode 125 and/or an outer edge of the first electrode 120. FIG. 5A schematically illustrates a cross-sectional view of an intermediate structure of the display substrate after the insulating portion 205 is formed. Thereafter, the light-emitting portion 115 and the second electrode 130 can be further formed on the display substrate on which the insulating portion 205 has been formed, to obtain the display substrate as shown in FIG. 2.

In some embodiments, step S315 can comprise simultaneously forming the auxiliary electrode 125 on the rib 111 of the pixel definition layer 110 and the first electrode 120 on the portion of the planarization layer 105 corresponding to the opening 112 of the pixel definition layer 110 (step S316). That is, the auxiliary electrode 125 and the first electrode 120 can be simultaneously formed. In this case, the auxiliary electrode 125 and the first electrode 120 have a same material. In this way, the process is simplified. For example, step S316 can comprise: simultaneously forming a first electrode stack 505 and an auxiliary electrode stack 510 in one patterning process (step S340), wherein the auxiliary electrode stack 510 comprises the auxiliary electrode 125 and a photoresist 515 on a side of the auxiliary electrode 125 away from the planarization layer, and the first electrode stack 505 comprises the first electrode 120 and a photoresist 516 on a side of the first electrode 120 away from the planarization layer. That is, in practice, the first electrode 120 and the auxiliary electrode 125 are formed when the first electrode stack 505 and the auxiliary electrode stack 510 are formed. FIG. 5B schematically illustrates a cross-sectional view of an intermediate structure of the display substrate formed with the first electrode stack 505 and the auxiliary electrode stack 510.

The process of forming the first electrode stack 505 and the auxiliary electrode stack 510 is specifically described below. FIG. 6 schematically illustrates a flowchart of a method of manufacturing a display substrate according to another embodiment of the present disclosure. As shown in FIG. 6, step S316 (e.g., step S340) can comprise the following steps.

In step S341, an electrode material layer is deposited on the rib of the pixel definition layer and the portion of the planarization layer corresponding to the opening of the pixel definition layer.

In step S342, a photoresist layer is coated on the electrode material layer.

In step S343, the photoresist layer on the electrode material layer is exposed and developed to expose a portion of the electrode material layer.

In step S344, the exposed portion of the electrode material layer is etched to obtain the first electrode stack and the auxiliary electrode stack.

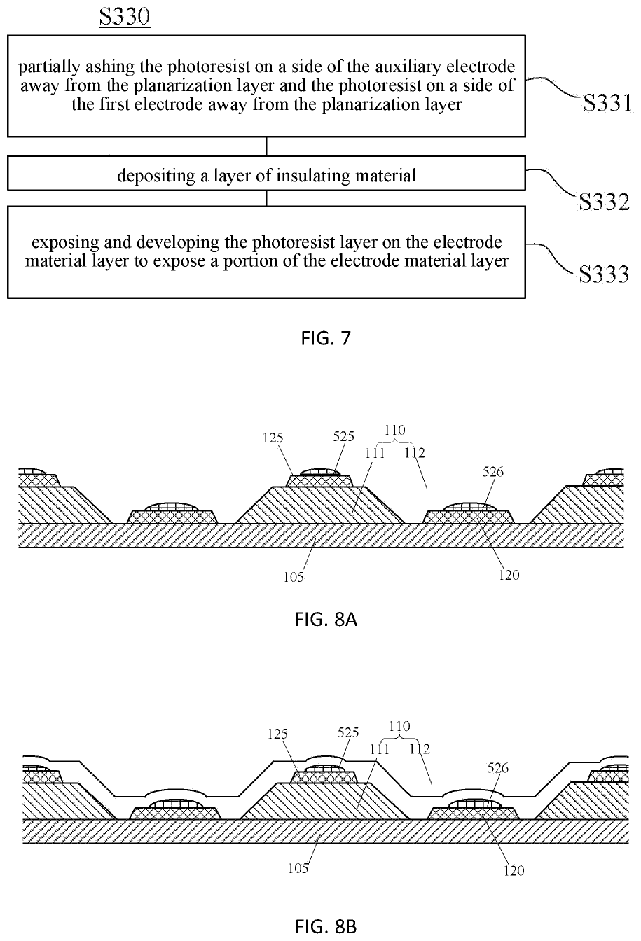

On this basis, the step of forming the insulating portion 205 between the auxiliary electrode 125 and the first electrode 120 (step S330) can be performed by asking the photoresists on the auxiliary electrode 125 and the first electrode 120. FIG. 7 schematically illustrates a flowchart of a method of manufacturing a display substrate according to still another embodiment of the present disclosure. As shown in FIG. 7, step S330 may comprise the following steps.

In step S331, the photoresist 515 on a side of the auxiliary electrode 125 away from the planarization layer 105 and the photoresist 516 on a side of the first electrode 120 away from the planarization layer 105 are partially asked, to expose an edge region of the auxiliary electrode 125 and an edge region of the first electrode 120.

In step S332, an insulating material layer is deposited.

In step S333, an unashed photoresist 525 on the auxiliary electrode 125 and an unashed photoresist 526 on the first electrode 120 are stripped, to make the insulating material on the stripped unashed photoresist removed and an unremoved insulating material forms the insulating portion 205.

By the method above, the process of forming the insulating portion does not need to strip the photoresists on the first electrode and the auxiliary electrode first, and does not need to perform traditional steps such as exposing, developing, etching either, which makes the process of forming the insulating portion simpler and saves masks.

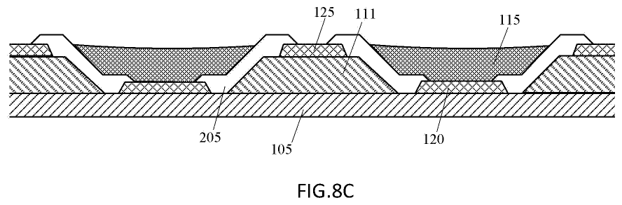

The process of forming the insulating portion 205 is described in detail below with reference to the drawings. Photoresist ashing is a process of removing the photoresist. For example, when the photoresist is placed in a plasma environment (e.g., an oxygen plasma environment), it will react with oxygen to generate volatile substances such as CO, CO₂, H₂O, N₂, and the like. It will be appreciated that after partial ashing, the volume of the remaining photoresist is smaller and a structure previously covered by the ashed photoresist is exposed. Therefore, for the auxiliary electrode stack 510 and the first electrode stack 505, after the photoresist 515 on the auxiliary electrode 125 and the photoresist 516 on the first electrode 120 are partially ashed, the edge of the auxiliary electrode 125 and the edge of the first electrode 120 will be exposed. The dimensions of the exposed edge portions of the auxiliary electrode 125 and the first electrode 120 can be controlled by controlling various parameters of the plasma environment, such as power, gas flow, etc., as well as controlling ashing time. FIG. 8A schematically illustrates a cross-sectional view of an intermediate structure of the display substrate obtained after the photoresists in the auxiliary electrode stack 510 and the first electrode stack 505 are partially ashed. The term “an edge portion” can be understood as a portion further away from a geometric center of the electrode in a direction parallel to the planarization layer, rather than the “side” of the electrode.

Then, the insulating material layer can be formed on the display substrate after the photoresists are partially ashed by processes such as CVD, PVD, PECVD. FIG. 8B schematically illustrates a cross-sectional view of the display substrate formed with the insulating material layer. Thereafter, the unashed photoresists 525, 526 on the auxiliary electrode 125 and the first electrode 120 can be stripped. In some embodiments, the unashed photoresists 525, 526 can be stripped by using an organic solvent (e.g., acetone). Due to the existence of pores in the insulating material layer, the organic solvent can pass through the insulating material layer through the pores and come into contact with the unashed photoresists. The unashed photoresists are dissolved in the organic solvent. The insulating material originally deposited on the unashed photoresists is removed from the display substrate along with the dissolution of the photoresist, while the insulating material deposited on the first electrode 120, the rib 111 and the auxiliary electrode 125 is not removed to form the insulating portion 205. Thereafter, the light-emitting portion 115 can be formed within the opening 112 by an inkjet printing process. FIG. 8C schematically illustrates a cross-sectional view of an intermediate structure of the display substrate after the light-emitting portion is formed. Then, the second electrode 130 can be formed on the auxiliary electrode 125 and the light-emitting portion 115. A structure of the obtained display substrate is shown in FIG. 2.

By the method of manufacturing the display substrate according to the present disclosure, the auxiliary electrode and the first electrode can be simultaneously manufactured in a same patterning process, and the insulating portion can be manufactured by means of photoresist asking, which saves the processes.

As will be apparent to those skilled in the art, many different ways of performing the methods of these embodiments of the present disclosure are possible. For example, the order of the steps can be changed, or some steps can be performed in parallel. In addition, other method steps can be inserted between the steps. Insertions may represent improvements to the methods such as those described herein, or may be unrelated to the methods. Furthermore, a given step may not have been fully completed before a next step begins.

It will be appreciated that the above embodiments are described by way of example only. While the embodiments have been illustrated and described in detail in the accompanying drawings and foregoing descriptions, such illustrations and descriptions are to be considered illustrative or exemplary and not restrictive, and the present invention is not limited to the disclosed embodiments. Additionally, it should be understood that the elements in the drawings are not necessarily drawn to scale, and that dimensions shown in the drawings are not intended to represent the actual or relative dimensions of the elements.

Other variations to the disclosed embodiments can be understood and effected by those skilled in the art in practicing the claimed invention, from a study of the drawings and the disclosure. In this disclosure, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims shall not be construed as the limitation of the scope. The use of first, second and similar words does not indicate any ordering. These words are to be construed as names.

1. A display substrate, comprising:
a planarization layer;
a pixel definition layer on the planarization layer, wherein the pixel definition layer comprises an opening and a rib surrounding the opening;
a first electrode on the planarization layer and within the opening;
a light-emitting portion located within the opening and electrically connected to the first electrode;
an auxiliary electrode on the rib of the pixel definition layer;
an insulating portion between the first electrode and the auxiliary electrode; and
a second electrode covering the auxiliary electrode and the light-emitting portion.

2. The display substrate according to claim 1, wherein the insulating portion partially covers at least one of the first electrode and the auxiliary electrode.

3. The display substrate according to claim 2, wherein the insulating portion covers at least one of:
an edge portion of a surface of the auxiliary electrode away from the planarization layer; and
an edge portion of a surface of the first electrode away from the planarization layer.

4. The display substrate according to claim 2, wherein the insulating portion partially covers the auxiliary electrode, and a maximum thickness of a portion of the insulating portion covering the auxiliary electrode in a direction perpendicular to the planarization layer is between 1000 Å and 2000 Å.

5. The display substrate according to claim 1, wherein the light-emitting portion comprises a functional layer formed from a precursor material, the rib comprises a single layer structure, and hydrophobicity of the insulating portion to the precursor material is higher than that of the single layer structure to the precursor material.

6. The display substrate according to claim 1, wherein the light-emitting portion comprises a functional layer formed from a precursor material, the rib comprises a stack of a plurality of layer structures, and hydrophobicity of the insulating portion to the precursor material is higher than that of a layer structure having a lowest hydrophobicity to the precursor material among the plurality of layer structures.

7. The display substrate according to claim 1, wherein the insulating portion covers a sidewall of the rib.

8. The display substrate according to claim 6, wherein the functional layer comprises a hole injection layer, a hole transport layer, a light-emitting material layer, an electron injection layer, and an electron transport layer.

9. The display substrate according to claim 7, wherein the sidewall and an upper surface of the planarization layer form an acute angle.

10. The display substrate according to claim 1, wherein the insulating portion comprises a water and oxygen barrier material.

11. The display substrate according to claim 1, further comprising a base substrate and a plurality of components on the base substrate, wherein the planarization layer is on the base substrate having the plurality of components.

12. A display device, comprising the display substrate according to claim 1.

13. A method of manufacturing a display substrate, comprising:
forming a planarization layer;
forming a pixel definition layer on the planarization layer, wherein the pixel definition layer comprises an opening and a rib surrounding the opening;
simultaneously forming an auxiliary electrode on the rib of the pixel definition layer and a first electrode on a portion of the planarization layer corresponding to the opening;
forming an insulating portion between the auxiliary electrode and the first electrode, wherein the insulating portion electrically insulates the auxiliary electrode from the first electrode;
forming a light-emitting portion on the first electrode; and
forming a second electrode on the auxiliary electrode and the light-emitting portion.

14. The method according to claim 13, wherein:
simultaneously forming the auxiliary electrode on the rib of the pixel definition layer and the first electrode on a portion of the planarization layer corresponding to the opening comprises:
simultaneously forming a first electrode stack and an auxiliary electrode stack in one patterning process, wherein the auxiliary electrode stack comprises the auxiliary electrode and a photoresist on a side of the auxiliary electrode away from the planarization layer, and the first electrode stack comprises the first electrode and a photoresist on a side of the first electrode away from the planarization layer; and
forming the insulating portion between the auxiliary electrode and the first electrode, comprising:
partially ashing the photoresist on the side of the auxiliary electrode away from the planarization layer and the photoresist on the side of the first electrode away from the planarization layer, to expose an edge region of the auxiliary electrode and an edge region of the first electrode;
depositing an insulating material layer; and
stripping an unashed photoresist on the auxiliary electrode and an unashed photoresist on the first electrode, to make the insulating material on the stripped unashed photoresist removed and an unremoved insulating material forms the insulating portion.

15. The method according to claim 14, wherein simultaneously forming the first electrode stack and the auxiliary electrode stack in one patterning process comprises:
depositing an electrode material layer on the rib of the pixel definition layer and the portion of the planarization layer corresponding to the opening;
coating a photoresist layer on the electrode material layer;
exposing and developing the photoresist layer on the electrode material layer to expose a portion of the electrode material layer; and
etching the exposed portion of the electrode material layer to obtain the first electrode stack and the auxiliary electrode stack.

16. The method according to claim 13, further comprising:
before forming the planarization layer, providing a base substrate and forming a plurality of components on the base substrate, wherein the planarization layer is formed on the base substrate on which the plurality of components are formed.

17. The method according to claim 13, wherein the light-emitting portion comprises a functional layer formed from a precursor material, the rib comprises a single layer structure, and hydrophobicity of the insulating portion to the precursor material is higher than that of the single layer structure to the precursor material.

18. The method according to claim 13, wherein the light-emitting portion comprises a functional layer formed from a precursor material, the rib comprises a stack of a plurality of layer structures, and hydrophobicity of the insulating portion to the precursor material is higher than that of a layer structure having a lowest hydrophobicity to the precursor material among the plurality of layer structures.

19. The method according to claim 17, wherein the functional layer comprises a hole injection layer, a hole transport layer, a light-emitting material layer, an electron injection layer, and an electron transport layer.

20. The method according to claim 13, wherein the insulating portion comprises a water and oxygen barrier material.
